(19) United States
(12) Patent Application Publication
(10) Pub. No.: US 2020/0212055 A1
(43) Pub. Date: Jul. 2, 2020

(54) INTEGRATION SCHEME FOR FERROELECTRIC MEMORY WITH A DEEP TRENCH STRUCTURE

(71) Applicant: Intel Corporation, Santa Clara, CA (US)

(72) Inventors: Chia-Ching LIN, Portland, OR (US); Sasikanth MANIPATRUNI, Portland, OR (US); Tanay GOSAVI, Hillsboro, OR (US); Dmitri NIKONOV, Beaverton, OR (US); Sou-Chi CHANG, Portland, OR (US); Uygar E. AVCI, Portland, OR (US); Ian A. YOUNG, Portland, OR (US)

(21) Appl. No.: 16/236,047

(22) Filed: Dec. 28, 2018

(51) Int. Cl. H01L 27/11507

(52) U.S. Cl. CPC H01L 27/11507

(57) ABSTRACT

A memory device comprises a trench within an insulating layer. A bottom electrode material is along sidewalls and a bottom of the trench, the bottom electrode material conformal to a top surface of the insulating layer. A ferroelectric material is conformal to the bottom electrode. A top electrode material is conformal to the ferroelectric material, wherein the bottom electrode material, the ferroelectric material and the top electrode material all extend above and across the top surface of the insulating layer.

### TECHNICAL FIELD

Embodiments of the disclosure are in the field of integrated circuit structures and, in particular, an integration scheme for ferroelectric memory with a deep trench structure.

### BACKGROUND

For the past several decades, the scaling of features in integrated circuits has been a driving force behind an ever-growing semiconductor industry. Scaling to smaller and smaller features enables increased densities of functional units on the limited real estate of semiconductor chips. For example, shrinking transistor size allows for the incorporation of an increased number of memory or logic devices on a chip, lending to the fabrication of products with increased capacity. The drive for ever-more capacity, however, is not without issue. The necessity to optimize the performance of each device becomes increasingly significant.

Variability in conventional and state-of-the-art fabrication processes may limit the possibility to further extend them into the sub-10 nm range. Consequently, fabrication of the functional components needed for future technology nodes may require the introduction of new methodologies or the integration of new technologies in current fabrication processes or in place of current fabrication processes.

### BRIEF DESCRIPTION OF THE DRAWINGS

FIG. 1 illustrates a ferroelectric trench capacitor in one embodiment.

FIGS. 2A and 2B illustrate fabrication steps for the ferroelectric trench capacitor.

FIG. 3 illustrates an integration scheme for a back-end memory device comprising a ferroelectric trench capacitor in accordance with the disclosed embodiments.

FIG. 4 illustrates the ferroelectric trench capacitor coupled to or integrated with a transistor to form a memory device according to one embodiment.

FIGS. 5A-5F illustrate cross-sectional views showing a process for fabricating a ferroelectric trench capacitor with a non-recessed bottom electrode in further detail.

FIGS. 6A and 6B are top views of a wafer and dies that include one or more ferroelectric trench capacitors having non-recessed bottom electrodes, in accordance with one or more of the embodiments disclosed herein.

FIG. 7 illustrates a block diagram of an electronic system, in accordance with an embodiment of the present disclosure.

FIG. 8 is a cross-sectional side view of an integrated circuit (IC) device assembly that may include one or more ferroelectric trench capacitors having non-recessed bottom electrodes, in accordance with one or more of the embodiments disclosed herein.

FIG. 9 illustrates a computing device in accordance with one implementation of the disclosure.

### DESCRIPTION OF THE EMBODIMENTS

An integration scheme for ferroelectric memory with a deep trench structure is described. In the following description, numerous specific details are set forth, such as specific material and tooling regimes, in order to provide a thorough understanding of embodiments of the present disclosure. It will be apparent to one skilled in the art that embodiments of the present disclosure may be practiced without these specific details. In other instances, well-known features, such as single or dual damascene processing, are not described in detail in order to not unnecessarily obscure embodiments of the present disclosure. Furthermore, it is to be understood that the various embodiments shown in the Figures are illustrative representations and are not necessarily drawn to scale. In some cases, various operations will be described as multiple discrete operations, in turn, in a manner that is most helpful in understanding the present disclosure, however, the order of description should not be construed to imply that these operations are necessarily order dependent. In particular, these operations need not be performed in the order of presentation.

Certain terminology may also be used in the following description for the purpose of reference only, and thus are not intended to be limiting. For example, terms such as “upper”, “lower”, “above”, “below,” “bottom,” and “top” refer to directions in the drawings to which reference is made. Terms such as “front”, “back”, “rear”, and “side” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

Embodiments described herein may be directed to front-end-of-line (FEOL) semiconductor processing and structures. FEOL is the first portion of integrated circuit (IC) fabrication where the individual devices (e.g., transistors, capacitors, resistors, etc.) are patterned in the semiconductor substrate or layer. FEOL generally covers everything up to (but not including) the deposition of metal interconnect layers. Following the last FEOL operation, the result is typically a wafer with isolated transistors (e.g., without any wires).

Embodiments described herein may be directed to back end of line (BEOL) semiconductor processing and structures. BEOL is the second portion of IC fabrication where the individual devices (e.g., transistors, capacitors, resistors, etc.) are interconnected with wiring on the wafer, e.g., the metallization layer or layers. BEOL includes contacts, insulating layers (dielectrics), metal levels, and bonding sites for chip-to-package connections. In the BEOL part of the fabrication stage contacts (pads), interconnect wires, vias and dielectric structures are formed. For modern IC processes, more than 10 metal layers may be added in the BEOL.

Embodiments described below may be applicable to FEOL processing and structures, BEOL processing and structures, or both FEOL and BEOL processing and structures. In particular, although an exemplary processing scheme may be illustrated using a FEOL processing scenario, such approaches may also be applicable to BEOL processing. Likewise, although an exemplary processing scheme may be illustrated using a BEOL processing scenario, such approaches may also be applicable to FEOL processing.

One or more embodiments described herein are directed to structures and architectures for fabricating a ferroelectric memory with a deep trench structure. Embodiments may include or pertain to one or more of memory, ferroelectric memory, embedded ferroelectric memory and system-on-chip (SoC) technologies.

One or more embodiments may be implemented to realize high embedded ferroelectric DRAM (FeRAM) to potentially increase monolithic integration of backend logic plus memory in SoCs of future technology nodes.

To continue the pace of improvements in microelectronic performance, computer memory needs to be scalable to smaller sizes. Ferroelectric memories, particularly memory architectures using new thin FE materials, provide a promising memory option for the future. In a particular configuration, FE memories may be expected to have a density that is three times denser than a standard SRAM cell, and be comparable to a 1T+1C (one-transistor one-capacitor) DRAM cell.

However, the state of the art integration scheme for back-end ferroelectric memory results in a ferroelectric device stack that includes a recessed bottom electrode and includes defects in the interfaces between materials comprising the ferroelectric device stack, which may limit applicability of ferroelectric memories.

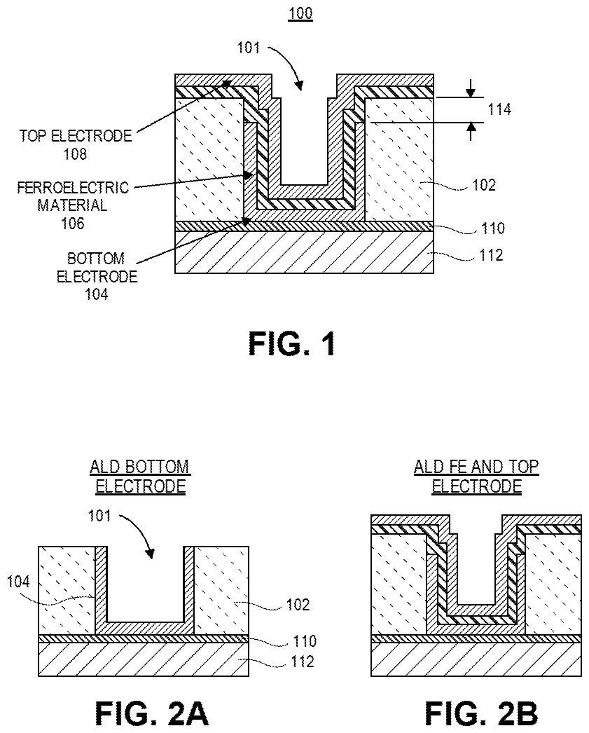

To provide context, FIGS. 1 and 2A-2B illustrate a state of the art integration scheme for a back-end memory device comprising a ferroelectric trench capacitor. FIG. 1 illustrates a ferroelectric trench capacitor in one embodiment. The ferroelectric trench capacitor 100 is formed in a trench 101 within an insulating layer 102. A bottom electrode 104 is along sidewalls and a bottom of the trench 101. A ferroelectric material 106 is conformal to a surface of the bottom electrode 104. And a top electrode 108 is conformal to the ferroelectric material 106. In one embodiment, the ferroelectric trench capacitor 100 may be formed on a barrier material 110, such as TaN, which is over an interconnect 112 comprising a metal such as Cu.

One drawback of the ferroelectric trench capacitor 100 is that to avoid shorting between bottom electrode 104 and the top electrode 108, the bottom electrode 104 is recessed from a top surface of the insulating layer 102 by particular distance 114, such as 10-20 nm, for example, recessing the bottom electrode 104 reduces the effective area per trench, and hence polarization of the ferroelectric trench capacitor 100.

FIGS. 2A and 2B illustrate fabrication steps for the ferroelectric trench capacitor 100. FIG. 2A shows the fabrication process after the bottom electrode 104 is deposited in the trench 101 via a first atomic layer deposition (ALD) process and then recessed away from the top surface of the trench 101. FIG. 2B shows the fabrication process after a second ALD or CVD (chemical vapor deposition) process is performed to deposit the ferroelectric material 106 and the top electrode 108 over the bottom electrode 104. Due to the need to recess the bottom electrode 104, two ALD processes are required, which results in an interface between the bottom electrode 104 and the ferroelectric material 106 that is chemically contaminated and has defects.

In accordance with one or more embodiments described herein, a memory device comprising a ferroelectric trench capacitor is fabricated such that the bottom electrode, the ferroelectric material and a top electrode are deposited in-situ in one ALD process (i.e., without breaking the vacuum of the ALD chamber). A memory device fabricated using such an architecture may exhibit a ferroelectric trench capacitor having a clean interface between the bottom electrode and the ferroelectric material and that has increased surface area compared to the state-of-the-art ferroelectric trench capacitor. In addition, the bottom electrode, the ferroelectric material and the top electrode along the sides and bottom of the trench, extend above and over the top surface of the trench. Thus, the disclosed embodiments describe a ferroelectric trench capacitor with a non-recessed bottom electrode.

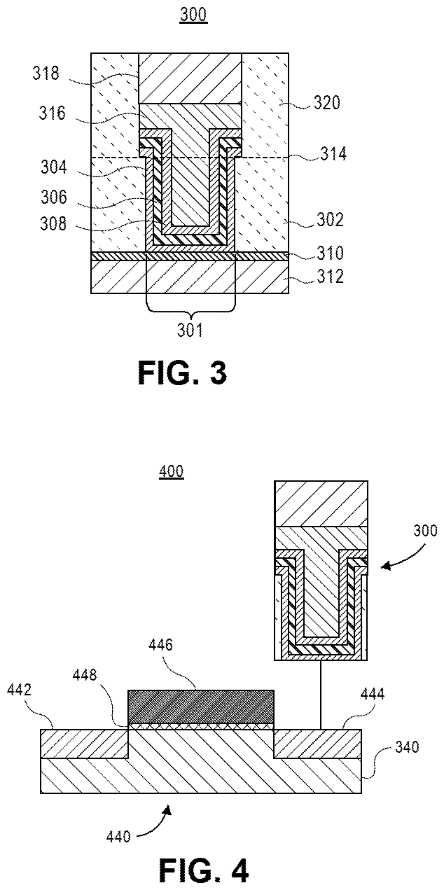

FIG. 3 illustrates an integration scheme for a back-end memory device comprising a ferroelectric trench capacitor in accordance with the disclosed embodiments. Similar to the embodiment of FIG. 1, the ferroelectric trench capacitor 300 is formed in a trench 301 within an insulating layer 302. A bottom electrode material 304 is along sidewalls and a bottom of the trench 301. According to one aspect of the disclosed embodiments, however, the bottom electrode material 304 is also conformal to a top surface 314 of the insulating layer 302 rather than being recessed from the top surface of the insulating layer 302. A ferroelectric material 306 is conformal to the bottom electrode material 304. A top electrode material 308 is conformal to the ferroelectric material 306.

According to the disclosed embodiments, the bottom electrode material 304, the ferroelectric material 306 and the top electrode material 308 all extend above and are on the top surface 314 of the insulating layer 302 and the trench 301. Accordingly, the disclosed embodiments provide a ferroelectric trench capacitor 300 with a non-recessed bottom electrode having a larger effective surface area compared to the state of the art ferroelectric trench capacitor of FIG. 1.

In some embodiments, the ferroelectric material comprising the ferroelectric trench capacitor 300 may include, for example, materials exhibiting ferroelectric behavior at thin dimensions, such as hafnium zirconium oxide (HfZrO, also referred to as HZO, which includes hafnium, zirconium, and oxygen), silicon-doped (Si-doped) hafnium oxide (which is a material that includes hafnium, oxygen, and silicon), germanium-doped (Ge-doped) hafnium oxide (which is a material that includes hafnium, oxygen, and germanium), aluminum-doped (Al-doped) hafnium oxide (which is a material that includes hafnium, oxygen, and aluminum), yttrium-doped (Y-doped) hafnium oxide (which is a material that includes hafnium, oxygen, and yttrium), lead zirconate titanate (which is a material that includes lead, zirconium, and titanium), barium zirconate titanate (which is a material that includes barium, zirconium and titanium), and combinations thereof. Some embodiments include hafnium, zirconium, barium, titanium, and/or lead, and combinations thereof. In one embodiment, the ferroelectric material 306 may range from approximately 2 to 50 nm in thickness.

In some embodiments, materials comprising the bottom electrode material 304 and the top electrode material 308 may include Ti, TiN or SrRuO₃ (SRO), as examples. The ferroelectric trench capacitor 300 may be formed on a barrier material 310, such as TaN, which is over a first interconnect 312. In some embodiments, a remaining portion of the trench 301 over the top electrode material 308 is filled in with a metal fill 316, and a second interconnect 318 is formed over the metal fill 316. In some embodiments, interconnects 312 and 318 and or the metal fill 316 can comprise conductive material(s) (e.g., metals, such as titanium nitride, tantalum nitride, platinum, copper, tungsten, tungsten nitride, and/or ruthenium, among other conductive materials and/or combinations thereof.

The memory device may be covered with a second insulating layer 320. In one embodiment, insulating layers 302 and 320 are an interlayer dielectric (ILD) layers. In one embodiment, insulating layers 302 and 320 are an oxide layer, e.g., a silicon oxide layer. In one embodiment, insulating layers 302 and 320 are a low-k dielectric, e.g., silicon dioxide, silicon oxide, carbon doped oxide (“CDO”), or any combination thereof. In one embodiment, insulating layers 302 and 320 include a nitride, oxide, a polymer, phosphosilicate glass, fluorosilicate (“SiOF”) glass, organosilicate glass (“SiOCH”), or any combination thereof. In another embodiment, insulating layers 302 and 320 are a nitride layer, e.g., silicon nitride layer. In alternative embodiments, insulating layers 302 and 320 are an aluminum oxide, silicon oxide nitride, other oxide/nitride layer, any combination thereof, or other electrically insulating layer determined by an electronic device design.

FIG. 4 illustrates the ferroelectric trench capacitor coupled to or integrated with a transistor to form a memory device according to one embodiment. In some embodiments, a memory device 400 includes a transistor, shown as a field effect transistor (FET) 440 with a source or drain terminal 442, a source or drain terminal 444, and a gate terminal 446 on an oxide layer 448 above a semiconductor material 340. In some embodiments, the memory device 400 is structured as a transistor plus FE capacitor (IT+1FE-CAP) memory, where the ferroelectric trench capacitor 300 is coupled to, or integrated with, a terminal (e.g., a source or drain 442 and 444) of the transistor 440. In one embodiment, the transistor 440 may be used for both read and write access to the ferroelectric trench capacitor 300.

According to a further aspect of the disclosed embodiments, the memory device 400 comprising the ferroelectric trench capacitor 300 is fabricated such that the bottom electrode material 304, the ferroelectric material 306 and the top electrode material 308 are deposited in-situ in one ALD process without breaking the vacuum of the ALD chamber. Consequently, an interface between the bottom electrode material 304 and the ferroelectric material 306 is clean and substantially free of defects and/or chemical contamination.

Generally, the process for fabricating the ferroelectric trench capacitor comprises forming a trench within an insulating layer. A bottom electrode material is formed along sidewalls and a bottom of the trench, the bottom electrode material is also conformal to a top surface of the insulating layer. A ferroelectric material is formed conformal to the bottom electrode. Finally, a top electrode material is formed conformal to the ferroelectric material, wherein the bottom electrode material, the ferroelectric material and the top electrode material form a film stack that extends above and across the top surface of the insulating layer.

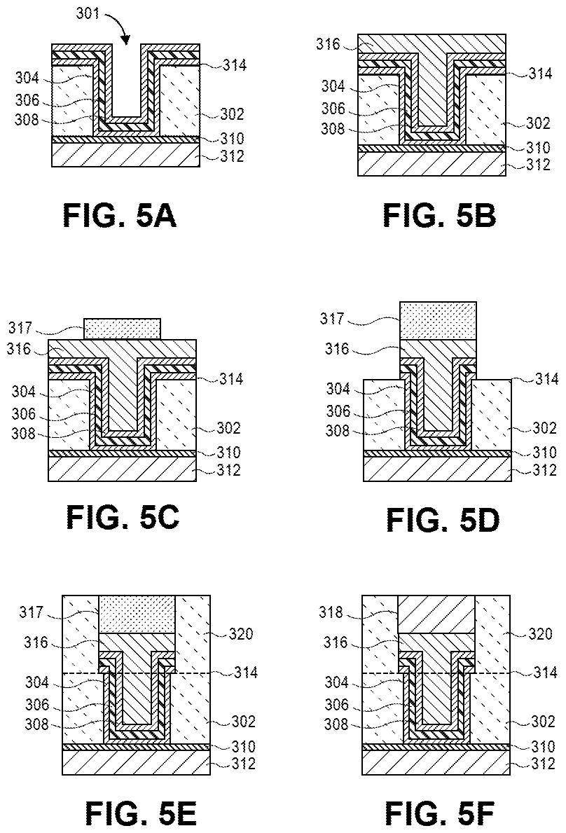

FIGS. 5A-5F illustrate cross-sectional views showing a process for fabricating a ferroelectric trench capacitor with a non-recessed bottom electrode in further detail, where like reference numerals from FIG. 3 have like reference numerals. FIG. 5A shows the process after a lithography step defines a trench location in the insulating layer and after trench 301 is etched into the insulating layer (e.g., by reactive ion etching process (RIE)). Also shown is that the trench 301 may be formed on a barrier material 310, such as TaN, which is over a first interconnect 312 comprising a metal such as Cu. A film stack comprising the bottom electrode material 304, the ferroelectric material 306 and the top electrode material 308 is then conformally deposited along the top surface 314 of the insulating layer 302 and along walls of the trench 301 by atomic layer deposition (ALD). According to one aspect of the disclosed embodiments, all three layers of the film stack, i.e., the bottom electrode material 304, the ferroelectric material 306 and the top electrode material 308, are grown in an ALD chamber in-situ. Growing the film stack in-situ eliminates any defects in the interface between the bottom electrode material and the ferroelectric material 306, as well as the interface between the ferroelectric material 306 and the top electrode material 308.

FIG. 5B illustrates the fabrication process after a metal fill 316 is used to gap-fill the remaining portion of the trench over the top electrode material 308 via a chemical vapor deposition (CVD) and chemical mechanical polishing (CMP) process, wherein the metal fill extends along a top surface of the film stack on the insulating layer 302. FIG. 5C illustrates the fabrication process after a hard mask 317 is patterned over the metal fill 316. The hard mask 317 is patterned to define the distance the film stack extends past walls of the trench 301 along the top surface of the insulating layer 302.

FIG. 5D illustrates the fabrication process after the a dry/wet etch is performed to etch back the film stack and the metal fill 316 over the top surface of the insulating layer 302 in alignment with the hard mask 317 to complete fabrication of the ferroelectric trench capacitor 300. FIG. 5E illustrates the fabrication process after a second insulating layer 320 is formed over the insulating layer 302. FIG. 5F illustrates the fabrication process after the hard mask 317 is removed by ash and replaced with another interconnect 318 over the ferroelectric trench capacitor.

In a further embodiment of the disclosure, a wet clean etch may be optionally performed to etch back the bottom electrode material 304 and the top electrode material 308 over the top surface 314 of the insulating layer 302 so that the ferroelectric material 306 extends past the bottom electrode material 304 and the top electrode material 308 to reduce a likelihood of shorting.

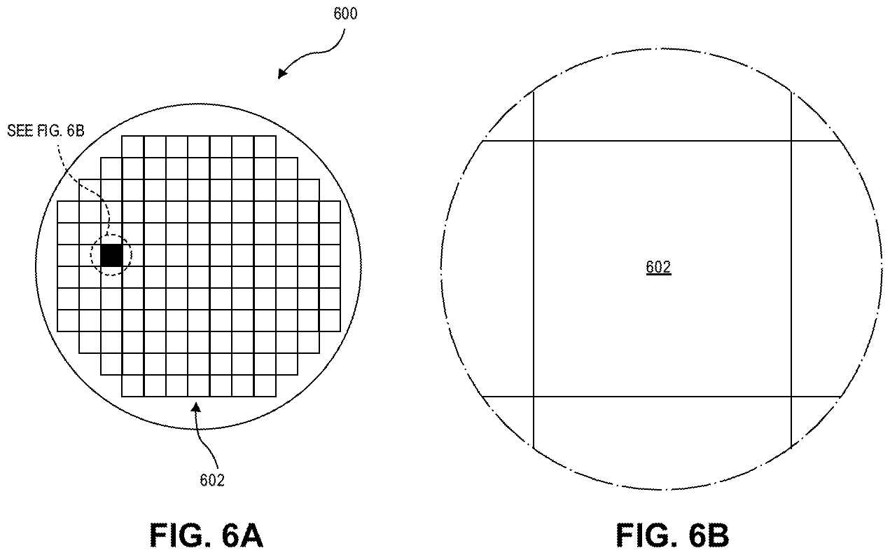

The integrated circuit structures described herein may be included in an electronic device. As an example of one such apparatus, FIGS. 6A and 6B are top views of a wafer and dies that include one or more ferroelectric trench capacitors having non-recessed bottom electrodes, in accordance with one or more of the embodiments disclosed herein.

Referring to FIGS. 6A and 6B, a wafer 600 may be composed of semiconductor material and may include one or more dies 602 having integrated circuit (IC) structures formed on a surface of the wafer 600. Each of the dies 602 may be a repeating unit of a semiconductor product that includes any suitable IC (e.g., ICs including one or more ferroelectric trench capacitors having non-recessed bottom electrodes, such as described above. After the fabrication of the semiconductor product is complete, the wafer 600 may undergo a singulation process in which each of the dies 602 is separated from one another to provide discrete “chips” of the semiconductor product. In particular, structures that include embedded non-volatile memory structures having an independently scaled selector as disclosed herein may take the form of the wafer 600 (e.g., not singulated) or the form of the die 602 (e.g., singulated). The die 602 may include one or more embedded non-volatile memory structures based independently scaled selectors and/or supporting circuitry to route electrical signals, as well as any other IC components. In some embodiments, the wafer 600 or the die 602 may include an additional memory device (e.g., a static random access memory (SRAM) device), a logic device (e.g., an AND, OR, NAND, or NOR gate), or any other suitable circuit element. Multiple ones of these devices may be combined on a single die 602. For example, a memory array formed by multiple memory devices may be formed on a same die 602 as a processing device or other logic that is configured to store information in the memory devices or execute instructions stored in the memory array.

Embodiments disclosed herein may be used to manufacture a wide variety of different types of integrated circuits and/or microelectronic devices. Examples of such integrated circuits include, but are not limited to, processors, chipset components, graphics processors, digital signal processors, micro-controllers, and the like. In other embodiments, semiconductor memory may be manufactured. Moreover, the integrated circuits or other microelectronic devices may be used in a wide variety of electronic devices known in the arts. For example, in computer systems (e.g., desktop, laptop, server), cellular phones, personal electronics, etc. The integrated circuits may be coupled with a bus and other components in the systems. For example, a processor may be coupled by one or more buses to a memory, a chipset, etc. Each of the processor, the memory, and the chipset, may potentially be manufactured using the approaches disclosed herein.

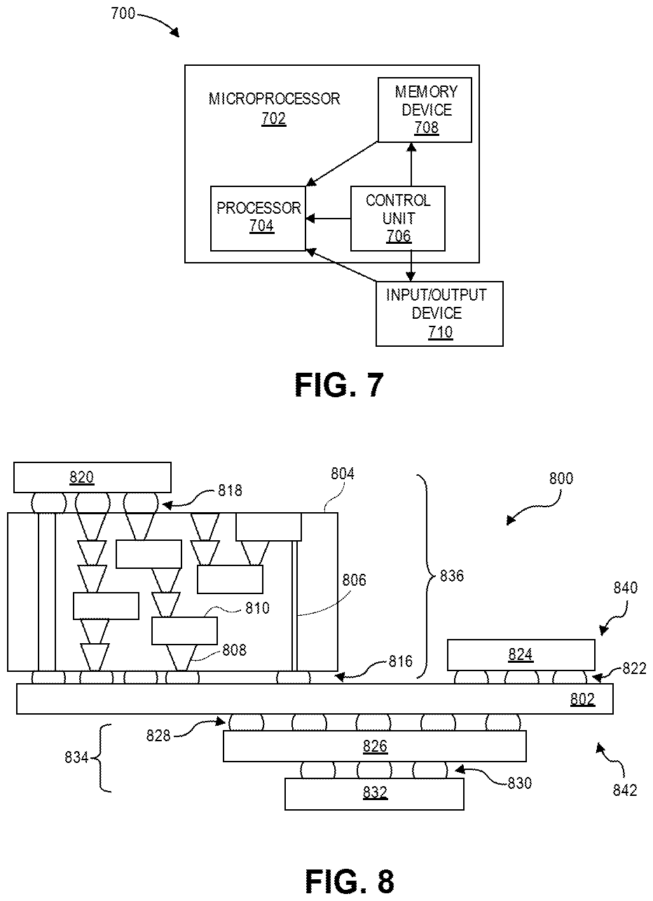

FIG. 7 illustrates a block diagram of an electronic system 700, in accordance with an embodiment of the present disclosure. The electronic system 700 can correspond to, for example, a portable system, a computer system, a process control system, or any other system that utilizes a processor and an associated memory. The electronic system 700 may include a microprocessor 702 (having a processor 704 and control unit 706), a memory device 708, and an input/output device 710 (it is to be appreciated that the electronic system 700 may have a plurality of processors, control units, memory device units and/or input/output devices in various embodiments). In one embodiment, the electronic system 700 has a set of instructions that define operations which are to be performed on data by the processor 704, as well as, other transactions between the processor 704, the memory device 708, and the input/output device 710. The control unit 706 coordinates the operations of the processor 704, the memory device 708 and the input/output device 710 by cycling through a set of operations that cause instructions to be retrieved from the memory device 708 and executed. The memory device 708 can include a non-volatile memory cell as described in the present description. In an embodiment, the memory device 708 is embedded in the microprocessor 702, as depicted in FIG. 7. In an embodiment, the processor 704, or another component of electronic system 700, includes one or more ferroelectric trench capacitors having non-recessed bottom electrodes, such as those described herein.

FIG. 8 is a cross-sectional side view of an integrated circuit (IC) device assembly that may include one or more ferroelectric trench capacitors having non-recessed bottom electrodes, in accordance with one or more of the embodiments disclosed herein.

Referring to FIG. 8, an IC device assembly 800 includes components having one or more integrated circuit structures described herein. The IC device assembly 800 includes a number of components disposed on a circuit board 802 (which may be, e.g., a motherboard). The IC device assembly 800 includes components disposed on a first face 840 of the circuit board 802 and an opposing second face 842 of the circuit board 802. Generally, components may be disposed on one or both faces 840 and 842. In particular, any suitable ones of the components of the IC device assembly 800 may include a number of ferroelectric trench capacitors having non-recessed bottom electrodes, such as disclosed herein.

In some embodiments, the circuit board 802 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 802. In other embodiments, the circuit board 802 may be a non-PCB substrate.

The IC device assembly 800 illustrated in FIG. 8 includes a package-on-interposer structure 836 coupled to the first face 840 of the circuit board 802 by coupling components 816. The coupling components 816 may electrically and mechanically couple the package-on-interposer structure 836 to the circuit board 802, and may include solder balls (as shown in FIG. 8), male and female portions of a socket, an adhesive, an underfill material, and/or any other suitable electrical and/or mechanical coupling structure.

The package-on-interposer structure 836 may include an IC package 820 coupled to an interposer 804 by coupling components 818. The coupling components 818 may take any suitable form for the application, such as the forms discussed above with reference to the coupling components 816. Although a single IC package 820 is shown in FIG. 8, multiple IC packages may be coupled to the interposer 804. It is to be appreciated that additional interposers may be coupled to the interposer 804. The interposer 804 may provide an intervening substrate used to bridge the circuit board 802 and the IC package 820. The IC package 820 may be or include, for example, a die (the die 602 of FIG. 6B), or any other suitable component. Generally, the interposer 804 may spread a connection to a wider pitch or reroute a connection to a different connection. For example, the interposer 804 may couple the IC package 820 (e.g., a die) to a ball grid array (BGA) of the coupling components 816 for coupling to the circuit board 802. In the embodiment illustrated in FIG. 8, the IC package 820 and the circuit board 802 are attached to opposing sides of the interposer 804. In other embodiments, the IC package 820 and the circuit board 802 may be attached to a same side of the interposer 804. In some embodiments, three or more components may be interconnected by way of the interposer 804.

The interposer 804 may be formed of an epoxy resin, a fiberglass-reinforced epoxy resin, a ceramic material, or a polymer material such as polyimide. In some implementations, the interposer 804 may be formed of alternate rigid or flexible materials that may include the same materials described above for use in a semiconductor substrate, such as silicon, germanium, and other group III-V and group IV materials. The interposer 804 may include metal interconnects 810 and vias 808, including but not limited to through-silicon vias (TSVs) 806. The interposer 804 may further include embedded devices, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio-frequency (RF) devices, power amplifiers, power management devices, antennas, arrays, sensors, and microelectromechanical systems (MEMS) devices may also be formed on the interposer 804. The package-on-interposer structure 836 may take the form of any of the package-on-interposer structures known in the art.

The IC device assembly 800 may include an IC package 824 coupled to the first face 840 of the circuit board 802 by coupling components 822. The coupling components 822 may take the form of any of the embodiments discussed above with reference to the coupling components 816, and the IC package 824 may take the form of any of the embodiments discussed above with reference to the IC package 820.

The IC device assembly 800 illustrated in FIG. 8 includes a package-on-package structure 834 coupled to the second face 842 of the circuit board 802 by coupling components 828. The package-on-package structure 834 may include an IC package 826 and an IC package 832 coupled together by coupling components 830 such that the IC package 826 is disposed between the circuit board 802 and the IC package 832. The coupling components 828 and 830 may take the form of any of the embodiments of the coupling components 816 discussed above, and the IC packages 826 and 832 may take the form of any of the embodiments of the IC package 820 discussed above. The package-on-package structure 834 may be configured in accordance with any of the package-on-package structures known in the art.

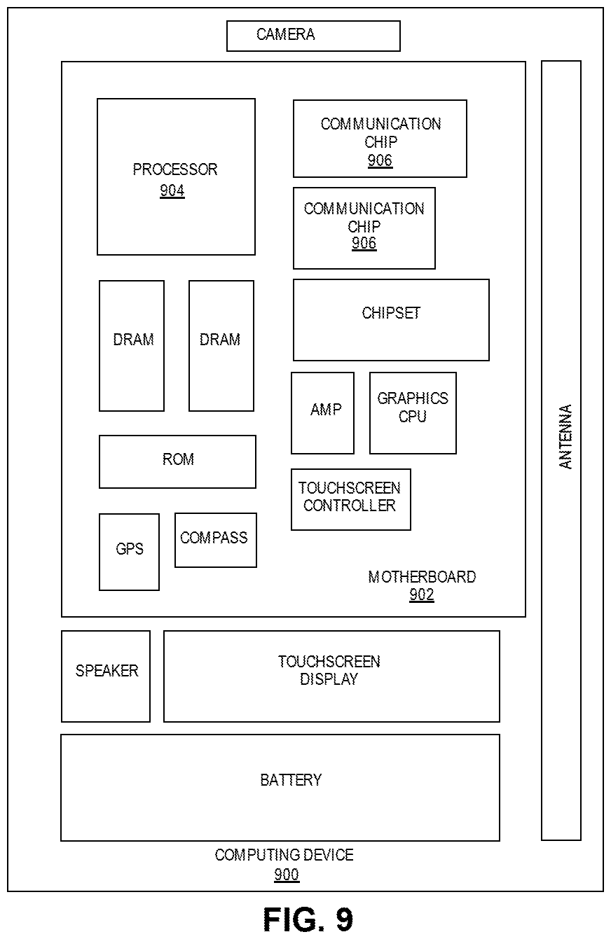

FIG. 9 illustrates a computing device 900 in accordance with one implementation of the disclosure. The computing device 900 houses a board 902. The board 902 may include a number of components, including but not limited to a processor 904 and at least one communication chip 906. The processor 904 is physically and electrically coupled to the board 902. In some implementations the at least one communication chip 906 is also physically and electrically coupled to the board 902. In further implementations, the communication chip 906 is part of the processor 904.

Depending on its applications, computing device 900 may include other components that may or may not be physically and electrically coupled to the board 902. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 906 enables wireless communications for the transfer of data to and from the computing device 900. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 906 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 900 may include a plurality of communication chips 906. For instance, a first communication chip 906 may be dedicated to shorter range wireless communications such as Wi-Fi and Bluetooth and a second communication chip 906 may be dedicated to longer range wireless communications such as GPS, EDGE, GPRS, CDMA, WiMAX, LTE, Ev-DO, and others.

The processor 904 of the computing device 900 includes an integrated circuit die packaged within the processor 904. In some implementations of the disclosure, the integrated circuit die of the processor includes one or more ferroelectric trench capacitors having non-recessed bottom electrodes, in accordance with implementations of embodiments of the disclosure. The term “processor” may refer to any device or portion of a device that processes electronic data from registers and/or memory to transform that electronic data into other electronic data that may be stored in registers and/or memory.

The communication chip 906 also includes an integrated circuit die packaged within the communication chip 906. In accordance with another implementation of embodiments of the disclosure, the integrated circuit die of the communication chip includes one or more ferroelectric trench capacitors having non-recessed bottom electrodes, in accordance with implementations of embodiments of the disclosure.

In further implementations, another component housed within the computing device 900 may contain an integrated circuit die that includes one or more ferroelectric trench capacitors having non-recessed bottom electrodes, in accordance with implementations of embodiments of the disclosure.

In various implementations, the computing device 900 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 900 may be any other electronic device that processes data.

Thus, embodiments described herein include ferroelectric trench capacitors having non-recessed bottom electrodes.

The above description of illustrated implementations of embodiments of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

### Example Embodiment 1

A memory device comprises a trench within an insulating layer. A bottom electrode material is along sidewalls and a bottom of the trench, the bottom electrode material conformal to a top surface of the insulating layer. A ferroelectric material is conformal to the bottom electrode. A top electrode material is conformal to the ferroelectric material, wherein the bottom electrode material, the ferroelectric material and the top electrode material all extend above and across the top surface of the insulating layer.

### Example Embodiment 2

The memory device of example embodiment 1, wherein the ferroelectric material comprises any combination of one or more of: hafnium, zirconium, and oxygen; hafnium, oxygen, and germanium; hafnium, oxygen, and aluminum; hafnium, oxygen, and yttrium; and lead, zirconium, and titanium.

### Example Embodiment 3

The memory device of example embodiment 1, wherein the ferroelectric material comprises one of: hafnium, zirconium, barium, and titanium; and hafnium, zirconium, barium, and lead.

### Example Embodiment 4

The memory device of example embodiment 1, wherein the ferroelectric material ranges from approximately 2 to 50 nm in thickness.

### Example Embodiment 5

The memory device of example embodiment 1, wherein the ferroelectric trench capacitor is on a barrier material, which is over a first interconnect.

### Example Embodiment 6

The memory device of example embodiment 1, wherein the trench is filled in with a metal fill and a second interconnect is over the metal fill, and wherein the memory device is covered with another insulating layer.

### Example Embodiment 7

The memory device of example embodiment 1, wherein the memory device comprises a transistor plus ferroelectric (FE) capacitor (IT+1FE-CAP) memory, wherein the ferroelectric trench capacitor is coupled to a source or a drain of the transistor, and wherein the transistor is used for both read and write access to the ferroelectric trench capacitor.

### Example Embodiment 8

A memory device, comprises a transistor; and a ferroelectric trench capacitor coupled to or integrated with a terminal of the transistor. The ferroelectric trench capacitor comprises a trench within an insulating layer; a bottom electrode material along sidewalls and a bottom of the trench, the bottom electrode material conformal to a top surface of the insulating layer; a ferroelectric material conformal to the bottom electrode; and a top electrode material conformal to the ferroelectric material. The bottom electrode material, the ferroelectric material and the top electrode material all extend above and are on the surface of the insulating layer and the trench.

### Example Embodiment 9

The memory device of example embodiment 8, wherein the ferroelectric material comprises any combination of one or more of: hafnium, zirconium, and oxygen; hafnium, oxygen, and germanium; hafnium, oxygen, and aluminum; hafnium, oxygen, and yttrium; and lead, zirconium, and titanium.

### Example Embodiment 10

The memory device of example embodiment 8, wherein the ferroelectric material comprises one of: hafnium, zirconium, barium, and titanium; and hafnium, zirconium, barium, and lead.

### Example Embodiment 11

The memory device of example embodiment 8, 9 or 10, wherein the ferroelectric material ranges from approximately 2 to 50 nm in thickness.

### Example Embodiment 12

The memory device of example embodiment 8, 9, 10 or 11, wherein the ferroelectric trench capacitor is on a barrier material, which is over a first interconnect.

### Example Embodiment 13

The memory device of example embodiment 8, 9, 10, 11 or 12, wherein the trench is filled in with a metal fill and a second interconnect is over the metal fill, and wherein the memory device is covered with another insulating layer.

### Example Embodiment 14

A method of fabricating a memory device comprises forming a trench within an insulating layer. A bottom electrode material is formed along sidewalls and a bottom of the trench, the bottom electrode material conformal to a top surface of the insulating layer. A ferroelectric material is formed conformal to the bottom electrode. Finally, a top electrode material is formed conformal to the ferroelectric material, wherein the bottom electrode material, the ferroelectric material and the top electrode material form a film stack that extends above and across the top surface of the first insulating layer.

### Example Embodiment 15

The method of example embodiment 14, wherein forming the ferroelectric material further comprises: forming a ferroelectric material using any combination of one or more of: hafnium, zirconium, and oxygen; hafnium, oxygen, and germanium; hafnium, oxygen, and aluminum; hafnium, oxygen, and yttrium; lead, zirconium, and titanium; hafnium, zirconium, barium, and titanium; and hafnium, zirconium, barium, and lead.

### Example Embodiment 16

The method of example embodiment 14 or 15, further comprising: forming a film stack comprising the bottom electrode material, the ferroelectric material, and the top electrode material, wherein the forming comprises conformably depositing the film stack along the top surface of the first insulating layer and along walls of the trench by atomic layer deposition (ALD).

### Example Embodiment 17

The method of example embodiment 16, further comprising: growing the film stack in an ALD chamber in-situ to eliminate any defects in an interface between the bottom electrode material and the ferroelectric material.

### Example Embodiment 18

The method of example embodiment 17, further comprising: growing the film stack in an ALD chamber in-situ to eliminate any defects in an interface between the ferroelectric material and the top electrode.

### Example Embodiment 19

The method of example embodiment 16, wherein forming the trench further comprises: forming the trench on a barrier material over a first interconnect.

### Example Embodiment 20

The method of example embodiment 17, further comprising: filling the remaining portion of the trench over the top electrode material with a metal fill, wherein the metal fill extends along the top surface of a film stack on the first insulating layer.

### Example Embodiment 21

The method of example embodiment 20, further comprising: patterning a hard mask over the metal fill to define a distance the film stack extends past the walls of the trench and over the top surface of the first insulating layer.

### Example Embodiment 22

The method of example embodiment 21, further comprising: etching back the film stack and the metal fill over the top surface of the first insulating layer and in alignment with the hard mask to complete fabrication of the ferroelectric trench capacitor.

### Example Embodiment 23

The method of example embodiment 22, further comprising: forming a second insulating layer over the first insulating layer.

### Example Embodiment 24

The method of example embodiment 23, further comprising: removing the hard mask and replacing the hard mask with a second interconnect over the ferroelectric trench capacitor.

### Example Embodiment 25

The method of example embodiment 24, further comprising: etching back the bottom electrode material and the top electrode material over the top surface of the first insulating layer so that the ferroelectric material extends past the bottom electrode material and the top electrode material.

What is claimed is:

1. A memory device, comprising:
a trench within an insulating layer;
a bottom electrode material along sidewalls and a bottom of the trench, the bottom electrode material conformal to a top surface of the insulating layer;
a ferroelectric material conformal to the bottom electrode material; and
a top electrode material conformal to the ferroelectric material, wherein the bottom electrode material, the ferroelectric material and the top electrode material all extend above and across the top surface of the insulating layer.

2. The memory device of claim 1, wherein the ferroelectric material comprises any combination of one or more of: hafnium, zirconium, and oxygen; hafnium, oxygen, and germanium; hafnium, oxygen, and aluminum; hafnium, oxygen, and yttrium; and lead, zirconium, and titanium.

3. The memory device of claim 1, wherein the ferroelectric material comprises one of: hafnium, zirconium, barium, and titanium; and hafnium, zirconium, barium, and lead.

4. The memory device of claim 1, wherein the ferroelectric material ranges from approximately 2 to 50 nm in thickness.

5. The memory device of claim 1, wherein the ferroelectric trench capacitor is on a barrier material, which is over a first interconnect.

6. The memory device of claim 1, wherein the trench is filled in with a metal fill and a second interconnect is over the metal fill, and wherein the memory device is covered with another insulating layer.

7. The memory device of claim 1, wherein the memory device comprises a transistor plus ferroelectric (FE) capacitor (IT+1FE-CAP) memory, wherein the ferroelectric trench capacitor is coupled to a source or a drain of the transistor, and wherein the transistor is used for both read and write access to the ferroelectric trench capacitor.

8. A memory device, comprising:
a transistor; and
a ferroelectric trench capacitor coupled to or integrated with a terminal of the transistor, the ferroelectric trench capacitor comprising:
a trench within an insulating layer;
a bottom electrode material along sidewalls and a bottom of the trench, the bottom electrode material conformal to a top surface of the insulating layer;
a ferroelectric material conformal to the bottom electrode material; and
a top electrode material conformal to the ferroelectric material, wherein the bottom electrode material, the ferroelectric material and the top electrode material all extend above and are on the top surface of the insulating layer and the trench.

9. The memory device of claim 8, wherein the ferroelectric material comprises any combination of one or more of: hafnium, zirconium, and oxygen; hafnium, oxygen, and germanium; hafnium, oxygen, and aluminum; hafnium, oxygen, and yttrium; and lead, zirconium, and titanium.

10. The memory device of claim 8, wherein the ferroelectric material comprises one of: hafnium, zirconium, barium, and titanium; and hafnium, zirconium, barium, and lead.

11. The memory device of claim 8, wherein the ferroelectric material ranges from approximately 2 to 50 nm in thickness.

12. The memory device of claim 8, wherein the ferroelectric trench capacitor is on a barrier material, which is over a first interconnect.

13. The memory device of claim 8, wherein the trench is filled in with a metal fill and a second interconnect is over the metal fill, and wherein the memory device is covered with another insulating layer.

14. A method of fabricating a memory device, the method comprising:
forming a trench within a first insulating layer;
forming a bottom electrode material along walls and a bottom of the trench, the bottom electrode material conformal to a top surface of the first insulating layer;
forming a ferroelectric material conformal to the bottom electrode material; and
forming a top electrode material conformal to the ferroelectric material, wherein the bottom electrode material, the ferroelectric material and the top electrode material all extend above and across the top surface of the first insulating layer.

15. The method of claim 14, wherein forming the ferroelectric material further comprises: forming a ferroelectric material using any combination of one or more of: hafnium, zirconium, and oxygen; hafnium, oxygen, and germanium; hafnium, oxygen, and aluminum; hafnium, oxygen, and yttrium; lead, zirconium, and titanium; hafnium, zirconium, barium, and titanium; and hafnium, zirconium, barium, and lead.

16. The method of claim 14, further comprising: forming a film stack comprising the bottom electrode material, the ferroelectric material, and the top electrode material, wherein the forming comprises conformably depositing the film stack along the top surface of the first insulating layer and along the walls of the trench by atomic layer deposition (ALD).

17. The method of claim 16, further comprising: growing the film stack in an ALD chamber in-situ to eliminate any defects in an interface between the bottom electrode material and the ferroelectric material.

18. The method of claim 17, further comprising: growing the film stack in the ALD chamber in-situ to eliminate any defects in an interface between the ferroelectric material and the top electrode material.

19. The method of claim 16, wherein forming the trench further comprises: forming the trench on a barrier material over a first interconnect.

20. The method of claim 17, further comprising: filling a remaining portion of the trench over the top electrode material with a metal fill, wherein the metal fill extends along the top surface of the film stack on the first insulating layer.

21. The method of claim 20, further comprising: patterning a hard mask over the metal fill to define a distance the film stack extends past the walls of the trench and over the top surface of the first insulating layer.

22. The method of claim 21, further comprising: etching back the film stack and the metal fill over the top surface of the first insulating layer and in alignment with the hard mask to complete fabrication of the ferroelectric trench capacitor.

23. The method of claim 22, further comprising: forming a second insulating layer over the first insulating layer.

24. The method of claim 23, further comprising: removing the hard mask and replacing the hard mask with a second interconnect over the ferroelectric trench capacitor.

25. The method of claim 24, further comprising: etching back the bottom electrode material and the top electrode material over the top surface of the first insulating layer so that the ferroelectric material extends past the bottom electrode material and the top electrode material.
